(19) United States
(12) Patent Application Publication
(10) Pub. No.: US 2007/0136632 A1
(43) Pub. Date: Jun. 14, 2007

(54) General-purpose procedure input circuit

(75) Inventor: Chang-Kuei Fu, Taoyuan Hsien (TW)

Correspondence Address: HDSL, 4331 STEVENS BATTLE LANE, FAIRFAX, VA, 22033, US

(73) Assignee: Delta electronics, Inc.

(21) Appl. No.: 11/264,340

(22) Filed: Oct. 28, 2005

(51) Int. Cl. G01R 31/30; G06F 11/00

(52) U.S. Cl. 714/745

(57) ABSTRACT

A general-purpose procedure input circuit receives a procedure input signal and at least one control signal. The general-purpose procedure input circuit includes a multiplexer, a signal attenuator and a ground circuit. The multiplexer includes a plurality of channels and receives the control signal to control one of the channels. The signal attenuator is electrically connected to the multiplexer and receives the procedure input signal. The procedure input signal is determined to be attenuated or not according to one of the conducted channels. The ground circuit is connected to the multiplexer and receives a ground signal. One of conducted channels is determined to be grounded or not according to the ground signal.

### BACKGROUND OF THE INVENTION

1. Field of the Invention

The present invention relates to a general-purpose procedure input circuit, more particularly to a general-purpose procedure input circuit without changing a packaged hardware and capable of processing signals of various levels for temperature or procedure control.

2. Description of Prior Art

For instruments such as temperature and procedure controller, a general-purpose procedure input circuit for the input types of Thermocouple, RDTmV, mA, and Volts. The conventional general-purpose procedure input circuit generally comprises a resistor for attenuation and match, a filter capacitor and a single-channel multiplexer. Afterward, an operational amplifier is used for filter and amplification.

FIG. 1 shows the circuit diagram of a conventional controller circuit. The controller 100 comprises an input interface 102 and an amplifier circuit 104. The input interface 102 comprises a multiplexer U1, resistors R1, R2, R3 and R4, capacitors C3 and C4, jumpers J1 and J2. The multiplexer U1 is functioned to receive signal RTD from the platinum resistor, the signal COLD_JNC from the cold contact compensation, selection signal A110, selection signal B108, selection signal C10. The input interface 102 receives procedure input signal THC+, THC− and working voltage. The amplifier circuit 104 comprises an amplifier OPA, resistors R5, R6, R7, capacitors C1, C2, C5, C6, C7. The resistors R1 and R5 are resistors with large resistance and the resistors R2 and R3 are resistors with attenuation function.

Moreover, the controller circuit should be adapted to receive signals of different levels, from tens μV of thermal coupler to 10 Volts of analog procedure input signals THC+ and THC−. The jumpers J1 and J2 shown in FIG. 1 are opened or shorted, or the channel of the multiplexer U1 is selected by software to provide input function for various levels. When the analog procedure input signals THC+ and THC− are small signals (such as in the case of thermal coupler), the jumper J1 should be short-circuited and the jumper J2 should be open circuited. On the contrary, when the analog procedure input signals THC+ and THC− are large signals such as 10 Volt signals, the jumper J1 should be open-circuited and the jumper J2 should be short-circuited. The multiplexer U1 switches the channel according to the signal RTD from the platinum resistor, the signal COLD_JNC from the cold contact compensation, selection signal A110, selection signal B108, and selection signal C10 in different time, as shown in the truth table of Table 1.

TABLE 1

Control Inputs

| | Select | | | ON Channels |
|---|---|---|---|---|
| INH | C | B | A | X |
| L | L | L | L | X0 |
| L | L | L | H | X1 |
| L | L | H | L | X2 |
| L | L | H | H | X3 |
| L | H | L | L | X4 |
| L | H | L | H | X5 |
| L | H | H | L | X6 |
| L | H | H | H | X7 |
| H | X | X | X | NONE |

X = Don't Care

However, the operation of opening circuit and shorting circuit for the jumpers J1 and J2 are not convenient for current technology. The case should be removed for opening circuit and shorting circuit the jumpers J1 and J2. Alternatively, mechanical switches are devised opening circuit and shorting circuit the jumpers J1 and J2.

As can be seen from above description, the temperature and procedure controller are subjected to limitation in procedure input end and cannot freely select temperature sensor and procedure input signal. The case should be removed for opening circuit and shorting circuit the jumpers even though the procedure input end can be selected. Alternatively, mechanical switches are required for opening circuit and shorting circuit the jumpers.

### SUMMARY OF THE INVENTION

The present invention is intended to provide a general-purpose procedure input circuit without changing a packaged hardware and capable of processing signals of various levels for temperature or procedure control.

Accordingly, the present invention provides a general-purpose procedure input circuit receiving a procedure input signal and at least one control signal. The general-purpose procedure input circuit includes a multiplexer, a signal attenuator and a ground circuit. The multiplexer includes a plurality of channels and receives the control signal to control one of the channels. The signal attenuator is electrically connected to the multiplexer and receives the procedure input signal. The procedure input signal is determined to be attenuated or not according to one of the conducted channels. The ground circuit is connected to the multiplexer and receives a ground signal. One of conducted channels is determined to be grounded or not according to the ground signal.

According to one aspect of the present invention, the resistance between channels is switched by conducting ground circuit such that one of the channel is grounded.

According to another aspect of the present invention, the operational amplifier circuit electrically connected to the multiplexer and received the procedure input signal processed by the multiplexer, the operational amplifier circuit filtering and amplifying the processed procedure input signal for outputting an output signal.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows the circuit diagram of a conventional controller circuit.

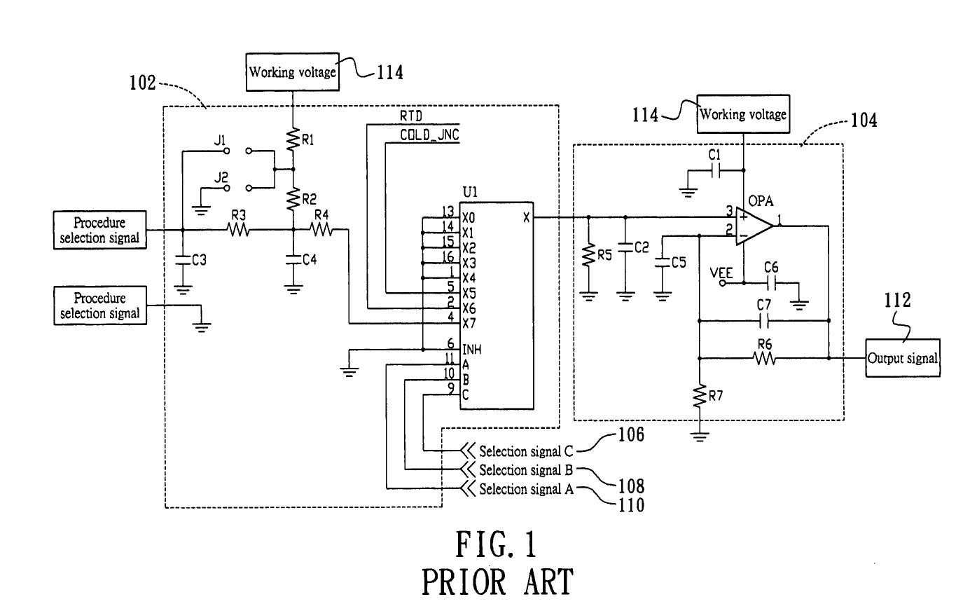

FIG. 2 shows a circuit diagram of the controller circuit according to the present invention.

### DETAILED DESCRIPTION OF THE INVENTION

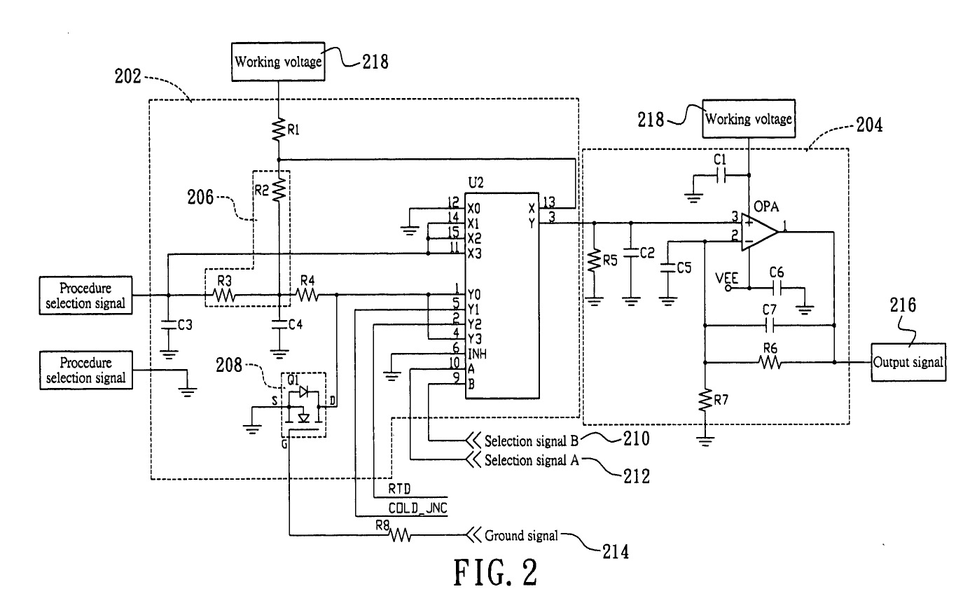

FIG. 2 shows a circuit diagram of the controller circuit according to the present invention. The controller circuit 200 comprises an input interface 202 and an amplifier circuit 204. The input interface 202 and the amplifier circuit 204 are operated under the working voltage 218. The input interface 202 comprises a multiplexer U2, a signal attenuation circuit 206, a ground circuit 208, resistors R1 and R4, capacitors C3 and C4. The amplifier circuit 204 comprises amplifier OPA, resistors R5, R6, R7 and capacitors C1, C2, C5, C6, C7.

The multiplexer U2 comprises a plurality of channels and receives signal A (212), signal B (210), platinum resistor signal and the cold contact compensation signal COLD_JNC. More particularly, the multiplexer U2 can be a dual-channel multiplexer and comprises channel X and channel Y. The channel Y of the multiplexer U2 is connected to the procedure input signal THC+ and THC− (Y0, Y3), cold contact compensation signal COLD_JNC (Y1), RTD signal Y2. The multiplexer U2 decides the conduction of channel thereof with reference to the signal A (212), signal B (210), cold contact compensation signal COLD_JNC (Y1), and RTD signal. The channel X of the multiplexer U2 decides to attenuate the procedure input signal THC+ and THC− or not.

The signal attenuation circuit 206 is electrically connected to the channel X3 of the multiplexer U2 and receives the procedure input signal THC+ and THC−. The signal attenuation circuit 206 will optionally attenuate the procedure input signal THC+ and THC− according to one of the conducted channels. The signal attenuation circuit 206 comprises resistor R2 and R3.

The ground circuit 208 is electrically connected to the multiplexer U2 and receives a ground signal 214 to determine whether one of the channels should be ground. The ground circuit 208 comprises a transistor Q1, wherein the transistor Q1 can be, but not limited to, one of N-type or P-type metal oxide semiconductor transistor. When channel Y is to be grounded, the transistor Q1 is turned on two switch the resistance of the channel Y0 and Y3 for grounding.

In the preferred embodiment, the transistor Q1 is turned to switch the resistance of the channel such that the conducted channel is grounded.

The amplifier circuit 204 comprises an amplifier OPA, resistors R5, R6, R7 and capacitors C1, C2, C5, C6, C7. The amplifier OPA receives the working voltage 218 and the negative working voltage VEE. The amplifier circuit 204 receives the processed procedure input signal THC+ and THC− from the multiplexer U2 and amplifies and filters the processed procedure input signal THC+ and THC− and then outputs an output signal 216.

In the preferred embodiment of the present invention, the resistors R1 and R5 are resistors with large resistance and the resistors R2 and R3 are resistors with attenuation function.

In the preferred embodiment of the present invention, when the procedure input signal THC+ and THC− are procedure input signal THC+ and THC− with large level such as 10 Volts, the control signal A and the control signal B of the multiplexer U2 selects the channel Y0 to be conducted. At the same time, the channel X is selected to be conducted to X0 and the resistor R2 is grounded. Therefore, the procedure input signal THC+ and THC− with large level is attenuated in proportion. When ground operation is necessary, the ground signal 214 is controlled to conduct the transistor Q1 and the channel Y0 is grounded.

When the procedure input signal THC+ and THC− is small signal such as signal of thermocouple, the control signal A and the control signal B of the multiplexer U2 selects the channel Y3 to be conducted. At the same time, the channel X is selected to be conducted to X3 such that the resistor R2 and the resistor R3 are connected in parallel to form an input resistance. When ground operation is necessary, the ground signal 214 is controlled to conduct the transistor Q1 and the channel Y3 is grounded.

Moreover, the multiplexer U2 will switch different channel in different time according to the truth table shown in Table 2 and RTD signal of the platinum resistor, the cold contact compensation signal COLD_JNC, the selection signal A (212) and the selection signal B (210).

TABLE 2

| Control Inputs | | |
|---|---|---|
| | Select | ON Channels |

| INH | B | A | Y | X |
|---|---|---|---|---|
| L | L | L | Y0 | X0 |
| L | L | H | Y1 | X1 |
| L | H | L | Y2 | X2 |
| L | H | H | Y3 | X3 |

| | | | |
|---|---|---|---|
| H | X | X | NONE |

X = Don't Care

In the preferred embodiment of the present invention, when the channel Y of the multiplexer U2 selects Y1 (RTD signal) or Y2 (cold contact compensation signal), the channel X is conduced to the procedure input signal THC+ terminal. Therefore, the resistor R2 and the resistor R3 form an input resistor.

In the preferred embodiment of the present invention, the controller can be temperature controller or procedure controller.

To sum up, the controller according to the present invention has following advantages:

1. The controller can be adapted to any procedure input without needing hardware or mechanic switch.

2. The circuit and component of the controller of the present invention are simple and the cost is reduced.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A general-purpose procedure input circuit used to receive a procedure input signal and at least one control signal, the general-purpose procedure input circuit comprising;
a multiplexer comprising a plurality of channels and conducting one of the channels with reference to the control signal;
a signal attenuator electrically connected to the multiplexer and receiving the procedure input signal and selectively attenuating the procedure input signal with reference to one conducted channel; and
a ground circuit electrically connected to the multiplexer and selectively grounding one of the conducted channels with reference to a ground signal.

2. The general-purpose procedure input circuit as in claim 1, wherein the ground circuit comprises a transistor.

3. The general-purpose procedure input circuit as in claim 2, wherein the transistor is turned on to switch resistance for the channel such that one of the conduced channels is grounded.

4. The general-purpose procedure input circuit as in claim 1, wherein the signal attenuator comprises a plurality of resistors.

5. The general-purpose procedure input circuit as in claim 1, wherein the multiplexer is electrically connected to an operational amplifier circuit.

6. The general-purpose procedure input circuit as in claim 5, wherein the operational amplifier circuit receives a processed procedure input signal from the multiplexer and filtering and amplifying the processed procedure input signal for outputting an output signal.

7. The general-purpose procedure input circuit as in claim 5, wherein the operational amplifier circuit comprises a plurality of filtering capacitors.

8. The general-purpose procedure input circuit as in claim 1, wherein the multiplexer is dual-channel multiplexer.

9. A controller receiving a procedure input signal, comprising:
a general-purpose procedure input circuit comprising:
a multiplexer comprising a plurality of channels and conducting one of the channels with reference to the control signal;
a signal attenuator electrically connected to the multiplexer and receiving the procedure input signal and selectively attenuating the procedure input signal with reference to one conducted channel; and
a ground circuit electrically connected to the multiplexer and selectively grounding one of the conducted channels with reference to a ground signal; and
an operational amplifier circuit electrically connected to the multiplexer for receiving the procedure input signal processed by the multiplexer, the operational amplifier circuit filtering and amplifying the processed procedure input signal for outputting an output signal.

10. The controller as in claim 9, wherein the ground circuit comprises a transistor.

11. The controller as in claim 10, wherein the transistor is turned on to switch resistance for the channel such that one of the conduced channels is grounded.

12. The controller as in claim 9, wherein the signal attenuator comprises a plurality of resistors.

13. The controller as in claim 9, wherein the operational amplifier circuit comprises a plurality of filtering capacitors.

14. The controller as in claim 9, wherein the multiplexer is a dual-channel multiplexer.

15. The controller as in claim 9, wherein the controller is a procedure controller.

16. The controller as in claim 9, wherein the controller is a temperature controller.
